(19) United States
(12) Patent Application Publication
(10) Pub. No.: US 2026/0314479 A1
(43) Pub. Date: Oct. 8, 2026

(54) Foundry Compatible, Ultra-low Resistance, Under-Bump-Metallization for Electroplated Bumps

(71) Applicant: IMEC VZW, Leuven (BE)

(72) Inventors: Vadiraj Manjunath Ananthapadmanabha Rao, Ghent (BE); Robert Miller, Lubbeek (BE)

(21) Appl. No.: 19/639,105

(22) Filed: Apr. 3, 2026

(30) Foreign Application Priority Data
Apr. 8, 2025 (EP) 25169061.6

(51) Int. Cl. H10W 74/10; H10W 72/00; H10W 72/20; H10W 74/01; H10W 74/40; H10W 90/00

(52) U.S. Cl. CPC H10W 74/147; H10W 72/012; H10W 72/2528; H10W 74/01; H10W 74/40; H10W 90/722

(57) ABSTRACT

Semiconductor structures for foundry compatible, ultra-low resistance, under-bump-metallization for electroplated bumps are described. An example semiconductor structure includes a semiconductor-based substrate. The semiconductor structure further includes a barrier layer disposed on the semiconductor-based substrate. The semiconductor structure also includes a seed layer disposed on the barrier layer. The barrier layer is configured to mitigate atom diffusion from the seed layer into the substrate. Moreover, the semiconductor structure includes a capping layer disposed on the seed layer. The capping layer is configured to resist oxidation of the seed layer. Additionally, the semiconductor structure includes a solder bump disposed on the capping layer.

### CROSS-REFERENCE TO RELATED APPLICATIONS

The present application is a non-provisional patent application claiming priority to European Patent EP 25169061.6, filed Apr. 8, 2025, the contents of which are hereby incorporated by reference.

### FIELD OF THE DISCLOSURE

The present disclosure generally relates to semiconductor processing. Particular embodiments relate to a semiconductor structure, a semiconductor system, and methods for producing a semiconductor.

### BACKGROUND

Three dimensional (3D) heterogeneous integration may provide a pathway towards building large-scale integrated systems, for example quantum computers. One component of this may involve the development of superconducting bumps that may facilitate bonding multiple chips together, routing signals between the chips, and galvanically connecting the different ground planes of the chips to minimize crosstalk. Indium (In), a soft superconducting metal, may be used for the bump material for cryogenic applications. However, working with In may pose some challenges depending on the deposition or growth technique used.

In bumps may involve a lift-off technique, where In may be evaporated and patterned on an under-bump-metallization (UBM) layer(s) on top of the superconducting material, which may include the quantum circuit. Use of UBM may hinder the formation of intermetallic compounds (IMC) with In and the quantum circuit material. These UBM layer(s), patterned using evaporation and lift-off techniques, may also aid with the adhesion of In. Advantage of the lift-off technique may include ease of fabrication and a variety of material choices that may be experimented with for the UBM layer(s) that may reduce etch selectivity for the different materials.

In semiconductor foundry manufacturing lift-off may be avoided and subtractive etch (wet/dry) may be used for patterning metal layers. Electrochemical deposition (ECD) may be used for growing/depositing solder bump material on a seed layer. The seed layer may include a low-resistivity material, which may provide a conduction path for currents in the bumping solder plating process. In semiconductor foundry processing for semiconductor integrated circuits, copper (Cu) may be used as the seed material in the plating process. For superconducting bump applications, electroplated In may be used. Cu is a non-superconducting material and may form IMC’s with In, which may induce losses in the bump stack for cryogenic applications, for example superconducting or quantum applications. Plating In, or any other suitable bump material, directly on superconducting materials acting as seed layers may be hindered by the fact that these superconducting materials may be resistive and may form a native oxide at room temperature. During the ECD process at room temperature or other known temperatures, this may result in no plating and/or result in non-uniform plating across the wafer.

The UBM layers and the In bumps may be fabricated using evaporation and lift-off.

Electroplated In bumps may be formed using Cu as a seed layer if the bumps are not superconducting.

### SUMMARY

Building large-scale integrated semiconductor systems, such as quantum computers using solid-state qubits, such as superconducting qubits, may involve functionalities that may be facilitated by heterogeneous 3D integration used in computing devices. One element for such scaling may involve the development of superconducting bumps, which may be used for galvanically connecting the different dies in the 3D stack. In advanced foundry semiconductor manufacturing processes that employ thermal-compression bonding techniques, ECD, electroplating may be a growth method for bumps. The electroplating or plating process may involve a seed material, such as a low resistance material like copper (Cu), which may provide a high-conductance path, during processing, for the plating currents thus facilitating uniform bump plating across the wafer. Indium (In), a superconducting soft metal, may form an intermetallic compound (IMC) with Cu. This formed IMC interface may add losses in the bump and may thereby limit the current-carrying capacity of the bump and may cause qubit decoherence in a quantum computing device.

The present disclosure may involve an under-bump-metallization layer in a semiconductor foundry-compatible setting, that facilitates production of ultra-low resistance, IMC-free, uniform bumps across a semiconductor wafer, for example a 300-millimeter (mm) wafer. The ultra-low resistance may be obtained at cryogenic or superconducting operating conditions that may be different from the processing conditions for the UBM. Embodiments according to the present disclosure are not limited to superconducting quantum applications.

Certain exemplary embodiments described herein may avoid IMC formation by introducing a capping material on top of the seed layer, over which the bump may be electroplated without compromising the required high conductance and uniformity of the plating process. In some embodiments, may have the potential to proximitize the seed layer and facilitate a fully superconducting bump stack, when the seed material is a non-superconductor. This integration structure may be adopted in a semiconductor foundry-compatible process flow to produce ultra-low resistance (potentially superconducting) UBM and associated bumps for quantum computing and/or other cryogenic applications.

In some embodiments, sputtered materials may be used for the UBM and the In may be electroplated using a resist mask. The UBM layers may be etched using subtractive techniques.

In a first aspect, a semiconductor structure is described. The semiconductor structure includes a semiconductor-based substrate. The semiconductor structure also includes a barrier layer disposed on the substrate. The semiconductor structure further includes a seed layer disposed on the barrier layer. The barrier layer is configured for mitigating atom diffusion from the seed layer into the substrate. Moreover, the semiconductor structure includes a capping layer disposed on the seed layer and configured for resisting oxidation of the seed layer. In addition, the semiconductor structure includes a solder bump disposed on the capping layer.

In some embodiments, wafer uniformity of the bumps from center to edge of the wafer may be improved without forming IMCs between seed and bump material.

The barrier layer may serve to protect the semiconductor-based substrate, which may for example include a semiconductor circuit, e.g., a quantum circuit, against further processing steps. Moreover, the barrier layer may improve seed layer adhesion compared to the seed layer directly on the substrate.

The solder bump may also be termed an electrode, in the sense that the solder bump is the part of the structure to which it may couple an external conductor on another die in an heterogenous system.

The substrate may be a semiconductor substrate, for example a Si substrate or a substrate on top of which a quantum circuit is disposed.

The substrate may include a conductive pattern, e.g., using a material configured to be superconducting under a critical temperature threshold, which may facilitate superconductivity in operation.

The capping layer may be deposited in situ.

The capping layer may also serve to mitigate IMC from forming during processing and/or bonding.

It is noted that the expression “A disposed on B” may mean that A is placed atop on and in physical contact with B.

In example embodiments, the barrier layer may be made of a material configured to be superconducting under a critical temperature threshold.

In example embodiments, the capping layer may be made of a material configured to be superconducting under a critical temperature threshold.

In example embodiments, the capping layer may be made of an oxidation-resistant material.

In example embodiments, the seed layer may be made of a metal material having a sheet resistance lower than 0.3 Ohms per square (Ohm/sq) at room temperature or any suitable temperature in the plating process.

The physical parameter “sheet resistance” does not have standardized SI units, Ohm/sq may be used.

In example embodiments, the seed layer may include any one or more of the following materials: Cu; Al; Ag; Ru; and Mo.

If the seed layer is made of a pure element, it may have improved conduction compared to alloys. Alloys of the mentioned materials may be also possible.

Some of the listed materials (e.g. Cu and Ag) may not be superconducting materials. However, in certain superconducting settings, this may be useful because they may have low electrical resistance.

In example embodiments, the barrier layer may include any one or more of the following materials TiN and TaN.

In example embodiments, the solder bump may be made of a material configured to be superconducting under a critical temperature threshold. The solder bump may be made of In or an InSn alloy.

The solder bump may be made of In. In may be a material configured to be superconducting under a critical temperature threshold. Furthermore, In may be also a good soldering material.

In example embodiments, the capping layer may include any one or more of the following materials: TiN; TaN; and Ru.

In example embodiments, the barrier layer may have a thickness within a range of 50–100 nanometers (nm); and/or the seed layer may have a thickness within a range of 25–100 nm; and/or the capping layer may have a thickness within a range of 10–50 nm; and/or the solder bump may have a thickness within a range of 5–15 µm. These thicknesses may be measured in a direction extending from the solder bump to a portion of the substrate closest to the solder bump.

In a second aspect, a semiconductor system is described. The semiconductor system includes a first semiconductor structure and a second semiconductor structure. The solder bump of the first semiconductor structure also serves as the solder bump of the second semiconductor structure. The first semiconductor structure and the second semiconductor structure are arranged diametrically opposed to each other from the perspective of their shared solder bump.

After bonding the first semiconductor structure and the second semiconductor structure, a semiconductor system may be formed where the solder bumps of both semiconductor structures may be a single solder bump. The solder bumps of both semiconductor structures may serve a common purpose and may be one solder bump. Both semiconductor structures may have, prior to bonding, their own solder bump that may be joined to a single solder bump after bonding. One of the semiconductor structures that may be bonded may have a solder bump according to the first aspect. The second semiconductor structure may not have a solder bump prior to bonding. The solder bump of the opposing semiconductor structure may be the common solder bump. In embodiments where the semiconductor does not have a solder bump prior to bonding a barrier, seed, and capping layer may be used prior to bonding.

In a third aspect, a method for producing a semiconductor structure is described. The method includes providing a semiconductor-based substrate. The method also includes forming a barrier layer on the substrate. The barrier layer is configured for blocking atom diffusion from the seed layer into the substrate. The method further includes forming a seed layer on the barrier layer. Moreover, the method includes forming a capping layer on the seed layer. The capping layer is configured for resisting oxidation of the seed layer. In addition, the method includes forming a solder bump on the capping layer.

In example embodiments, the method also includes removing any oxidation from the capping layer prior to the step of forming the solder bump.

In a fourth aspect, a method for producing a semiconductor system is described. The method includes producing a first semiconductor structure. The method also includes producing a second semiconductor structure. The solder bump of the first semiconductor structure also serves as the solder bump of the second semiconductor structure. The first semiconductor structure and the second semiconductor structure are arranged diametrically opposed to each other from the perspective of their shared solder bump.

In example embodiments, both the semiconductors may have solder bumps prior to bonding. In some embodiments, one semiconductor may have a solder bump prior to bonding whereas the other may not have a solder bump. In some embodiments, the forming of the solder bump on the capping layer may be the bonding process. The solder bump of the first semiconductor, which may be present prior to bonding may be the solder bump of the second semiconductor structure.

It will be understood by the skilled person that various specific features, advantages, and technical considerations applying to the above-described embodiments of the electronic structure according to the present disclosure may also apply to embodiments of the method, mutatis mutandis. In particular, any structure embodiment described above or below in the present disclosure will be understood by the skilled person to have or potentially have a corresponding method embodiment, and vice versa.

### BRIEF DESCRIPTION OF THE FIGURES

The above, as well as additional, features will be better understood through the following illustrative and non-limiting detailed description of example embodiments, with reference to the appended drawings.

FIG. 1 shows a bump cross-section diagram, according to example embodiments.

FIG. 2 illustrates a semiconductor structure, according to example embodiments.

FIG. 3 illustrates the integration of the bump on top of a superconducting material, according to example embodiments.

FIG. 4 illustrates a method for producing a semiconductor structure, according to example embodiments.

All the figures are schematic, not necessarily to scale, and generally only show parts which are necessary to elucidate example embodiments, wherein other parts may be omitted or merely suggested.

### DETAILED DESCRIPTION

Example embodiments will now be described more fully hereinafter with reference to the accompanying drawings. That which is encompassed by the claims may, however, be embodied in many different forms and should not be construed as limited to the embodiments set forth herein; rather, these embodiments are provided by way of example. Furthermore, like numbers refer to the same or similar elements or components throughout.

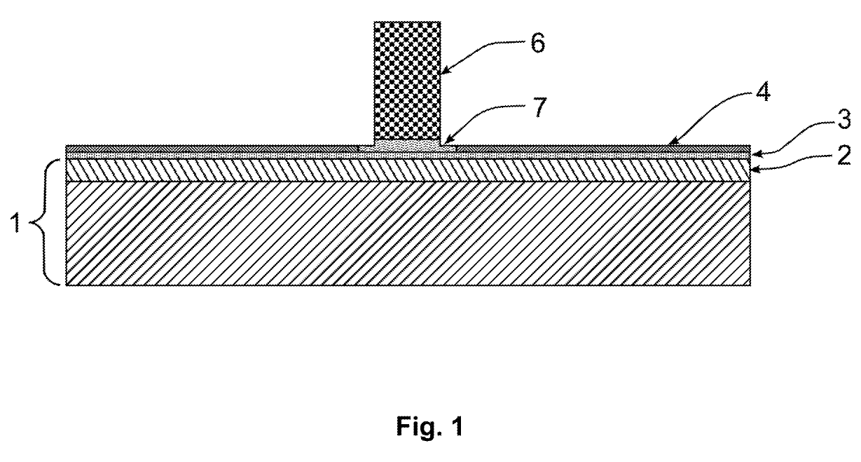

FIG. 1 shows a bump cross-section diagram, according to example embodiments. The bump material 6 may be In and may be plated on a seed layer 4 that may be Cu, which may thereby form an IMC 7. IMC 7 may result in added loss in the bump stack, which may limit the current carrying capacity of the bump when used to connect signal lines in quantum circuits.

In example embodiments, capping material 5 may be used, which may prevent the formation of the IMC 7 between the bump material 6 and the seed layer 4. The capping layer 5 may not compromise the high conductivity for bump plating as the resistance of the capping layer 5 may be in parallel to that of the seed layer 4. The conductivity of this tri-layer stack may be dominated by the seed layer 4, which may facilitate the uniformity of the electroplating process. Two quantum chips may be bonded together using the bump and the path of the superconducting path may be indicated by an arrow.

As depicted in FIG. 1, bumps may be directly on top of seed layer 4. IMC 7 formation of bump with seed material may occur, which may result in a lossy interface in the bump stack.

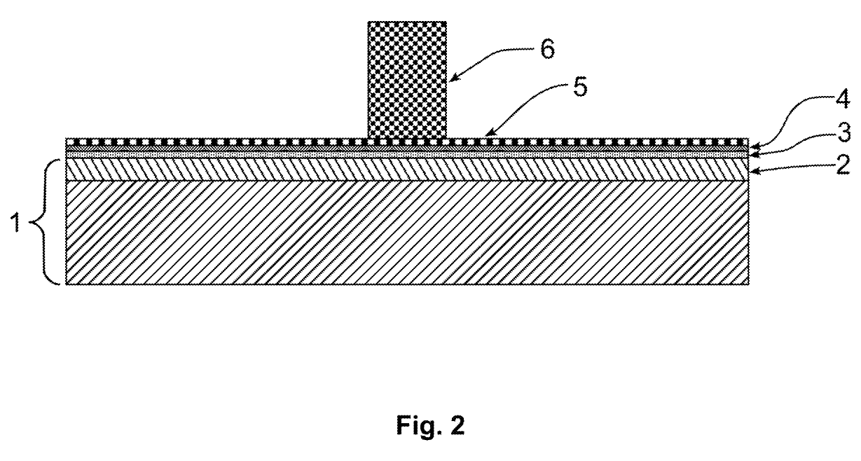

FIG. 2 illustrates a semiconductor structure, according to example embodiments.

In example embodiments, a conductive capping material 5, e.g., one that is superconducting, may prevent IMC 7 formation and may proximitize the seed material.

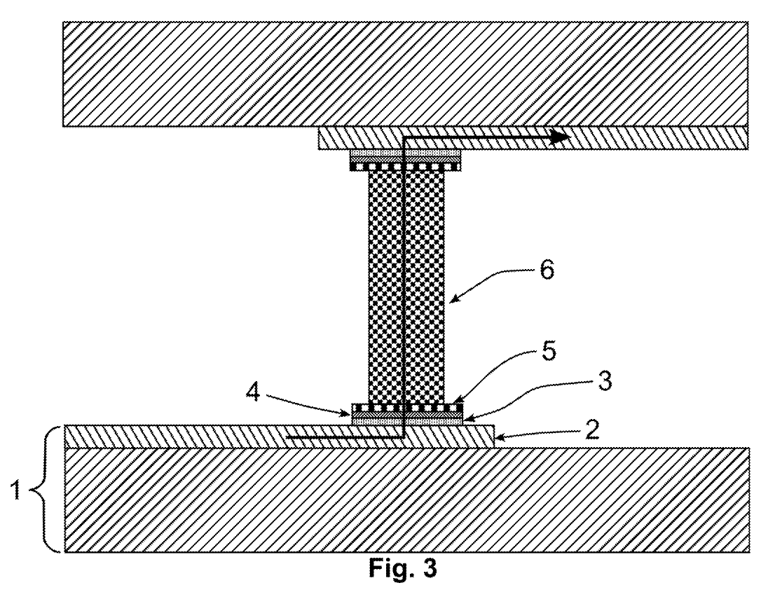

FIG. 3 illustrates the integration of the bump on top of a superconducting material, according to example embodiments. FIG. 3 a cross-section of a device. In some embodiments, the device may include bumps fabricated as described above on top of a suitable superconducting material. The bump may be part of a signal line connecting the bottom and the top structures. This signal path may be ultra-low resistance, e.g., superconducting, during operation.

The integration of the bump on top of a superconducting material may form a semiconductor system. Two semiconductor structures, dies, chips or equivalents (e.g., bottom and top), each may have superconducting circuits, for example quantum circuits. These structures may be bonded together using the bump fabrication process described herein. The cap 5, seed 4 and barrier 3 materials may be selectively etched with respect to the other circuit material after the electroplating process.

One of the advantages of the systems and methods described herein may be the potential for using proximity induced superconductivity effects. By choosing appropriate superconducting materials for the barrier and capping layers, the seed layer 4 may be proximitized. In doing so, superconducting bump connections may be obtained, even when the seed layer 4 is a non-super conducting metal. Facilitating this functionality may make integration of such a device simpler, without introducing potential lossy interfaces, such as the IMC 7.

The barrier layer 3 may act as a barrier layer between the seed layer 4 and the substrate 1. The substrate may include a circuit 2, which may be a superconducting, cryogenic, or quantum-circuit. Therefore, the barrier layer 3 may also protect any potentially present circuit 2, which may be part of the substrate 1, during further processing. The barrier layer 3 may also serve as an adhesion layer for the seed layer to the substrate. The barrier layer 3 may be in between the outer layer of the substrate 1, which may be the outer layer of the circuit 2, if present, and the seed layer 4.

The barrier layer may be superconducting with a high Tc, may feature good adhesion to Si, and/or may be selectively etched to the exposed materials.

The barrier layer may include TiN or TaN. The barrier layer may include a layered combination of TiN and TaN. Other materials or sandwiches thereof that are configured for mitigating atom diffusion from the seed layer 4 into the substrate 1 may also be possible.

The seed layer 4 may be used for the ECD, i.e. electroplating process, and/or may help to facilitate uniformity of the plating.

The seed layer may feature high conductivity, may be a superconductor (e.g., Ru), may have comparable resistivity to Cu at room temperature, may feature good adhesion to the barrier layer, may be deposited in situ with the barrier layer, may be thin enough for uniform plating, and/or may be selectively etched to the barrier layer and other exposed materials during the etching process.

The capping layer 5 may reduce or prevent the formation of IMC 7 between the bump 6 and the seed layer 4.

The capping layer may be superconducting and may have a high Tc, may be native-oxide free, may be plated with a bump material (e.g., In), may not form an IMC 7 with the bump material, may be thin, may be deposited in situ with the barrier layer 3 and the seed layer 4, and/or may be selectively etched to the seed and any other exposed material during the etch.

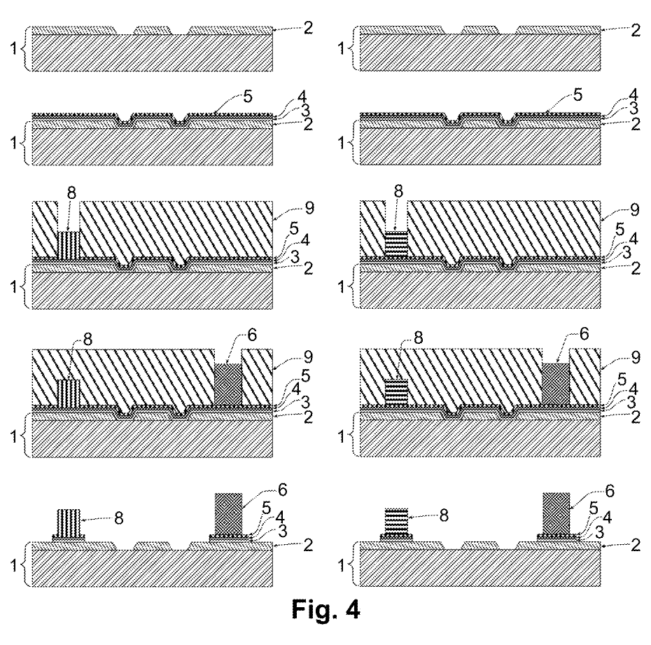

FIG. 4 illustrates a method for producing a semiconductor structure, according to example embodiments.

While some embodiments have been illustrated and described in detail in the appended drawings and the foregoing description, such illustration and description are to be considered illustrative and not restrictive. Other variations to the disclosed embodiments can be understood and effected in practicing the claims, from a study of the drawings, the disclosure, and the appended claims. The mere fact that certain measures or features are recited in mutually different dependent claims does not indicate that a combination of these measures or features cannot be used. Any reference signs in the claims should not be construed as limiting the scope.

What is claimed is:

1. A semiconductor structure comprising:
a semiconductor-based substrate;
a barrier layer disposed on the semiconductor-based substrate;
a seed layer disposed on the barrier layer, wherein the barrier layer is configured to mitigate atom diffusion from the seed layer into the semiconductor-based substrate;
a capping layer disposed on the seed layer, wherein the capping layer is configured to resist oxidation of the seed layer; and
a solder bump disposed on the capping layer.

2. The semiconductor structure of claim 1, wherein the barrier layer comprises a material configured for being superconducting under a critical temperature threshold.

3. The semiconductor structure of claim 1, wherein the capping layer comprises a material configured to be superconducting under a critical temperature threshold.

4. The semiconductor structure of claim 1, wherein the capping layer comprises an oxidation-resistant material.

5. The semiconductor structure of claim 1, wherein the seed layer comprises a metal material having a sheet resistance lower than 0.3 Ohm/sq.

6. The semiconductor structure of claim 1, wherein the seed layer comprises Cu, Al, Ag, Ru, or Mo.

7. The semiconductor structure of claim 1, wherein the barrier layer comprises TiN or TaN.

8. The semiconductor structure of claim 1, wherein the capping layer comprises TiN, TaN, or Ru.

9. The semiconductor structure of claim 1, wherein the solder bump comprises a material configured to be superconducting under a critical temperature threshold.

10. The semiconductor structure of claim 1, wherein the solder bump comprises In.

11. The semiconductor structure of claim 10, wherein the solder bump comprises an InSn alloy.

12. The semiconductor structure of claim 1, wherein the barrier layer has a thickness between 50 nanometers and 100 nanometers.

13. The semiconductor structure of claim 1, wherein the seed layer has a thickness between 50 nanometers and 100 nanometers.

14. The semiconductor structure of claim 1, wherein the capping layer has a thickness between 25 nanometers and 50 nanometers.

15. The semiconductor structure of claim 1, wherein the solder bump has a thickness between 5 microns and 15 microns.

16. A semiconductor system comprising:
a first semiconductor structure comprising a first solder bump; and
a second semiconductor structure comprising a second solder bump, wherein the first solder bump is the second solder bump.

17. A method comprising:
providing a semiconductor-based substrate;
forming a barrier layer on the semiconductor-based substrate;
forming a seed layer on the barrier layer, wherein the barrier layer is configured to block atom diffusion from the seed layer into the semiconductor-based substrate;
forming a capping layer on the seed layer, wherein the capping layer is configured to resist oxidation of the seed layer; and
forming a solder bump on the capping layer.

18. The method of claim 17, further comprising:
removing oxidation from the capping layer prior to forming the solder bump on the capping layer.

19. The method of claim 17, wherein the seed layer has a thickness between 50 nanometers and 100 nanometers.

20. The method of claim 17, wherein the capping layer has a thickness between 25 nanometers and 50 nanometers.
